(19) United States
(12) Patent Application Publication
(10) Pub. No.: US 2023/0005913 A1
(43) Pub. Date: Jan. 5, 2023

(54) MEMORY AND MANUFACTURING METHOD THEREOF

(71) Applicant: CHANGXIN MEMORY TECHNOLOGIES, INC., Hefei City (CN)

(72) Inventor: Kui ZHANG, Hefei City (CN)

(73) Assignee: CHANGXIN MEMORY TECHNOLOGIES, INC., Hefei City (CN)

(21) Appl. No.: 17/448,884

(22) Filed: Sep. 25, 2021

Related U.S. Application Data
(63) Continuation of application No. PCT/CN2021/106510, filed on Jul. 15, 2021.

(30) Foreign Application Priority Data
Jul. 5, 2021 (CN) 202110757209.2

(51) Int. Cl. H01L 27/108; H01L 29/78; H01L 29/66

(52) U.S. Cl. CPC H01L 27/10802; H01L 29/7841; H01L 29/7827; H01L 29/66666

(57) ABSTRACT

A memory includes: a substrate; a transistor array including multiple transistors on a surface of the substrate, conducting channels of the transistors extending in a direction perpendicular to the surface of the substrate; and a storage layer, disposed at a side of the conducting channel of each transistor, communicated with the conducting channel of the transistor, and configured to store charges and perform charge transfer with the communicated conducting channel.

### CROSS-REFERENCE TO RELATED APPLICATIONS

This application is a continuation of International Application No. PCT/CN2021/106510 filed on Jul. 15, 2021, which claims priority to Chinese Patent Application No. 202110757209.2 filed on Jul. 5, 2021. The disclosures of these applications are hereby incorporated by reference in their entirety.

### BACKGROUND

With the continuous growth of semiconductor market demand, a semiconductor memory technology develops rapidly, and a manufacturing technology for a memory, especially a Dynamic Random-Access Memory (DRAM) technology has developed rapidly, and has occupied a main position in a memory market. A common DRAM cell is of a 1T1C structure including one transistor and one capacitor, and logic states are distinguished according to whether charges are stored on the capacitor.

### SUMMARY

Embodiments of the present disclosure relate to, but not limited to, a memory and a manufacturing method thereof.

In a first aspect, a memory includes: a substrate; a transistor array including multiple transistors on a surface of the substrate, conducting channels of the transistors extending in a direction perpendicular to the surface of the substrate; and a storage layer, disposed at a side of the conducting channel of each transistor, communicated with the conducting channel of the transistor, and configured to store charges and perform charge transfer with the communicated conducting channel.

In a second aspect, a manufacturing method for a memory includes: forming a transistor array including multiple transistors on a surface of a substrate, conducting channels of the transistors extending in a direction perpendicular to the surface of the substrate; and forming a storage layer on a side surface of each transistor in the direction perpendicular to the surface of the substrate, the storage layer being communicated with the transistor and configured to store charges and perform charge transfer with the communicated conducting channel.

### BRIEF DESCRIPTION OF THE DRAWINGS

The accompanying drawings referred to in the specification are a part of this disclosure, and provide illustrative embodiments consistent with the disclosure and, together with the detailed description, serve to illustrate some embodiments of the disclosure.

FIG. 1 is a first schematic structural diagram of a memory according to some embodiments of the present disclosure.

FIG. 2 is a second schematic structural diagram of a memory according to some embodiments of the present disclosure.

FIG. 3 is a third schematic structural diagram of a memory according to some embodiments of the present disclosure.

FIG. 4 is a fourth schematic structural diagram of a memory according to some embodiments of the present disclosure.

FIG. 5 is a schematic flowchart of a manufacturing method for a memory according to some embodiments of the present disclosure.

FIG. 6A is a schematic diagram of substrate doping in a manufacturing method for a memory according to some embodiments of the present disclosure.

FIG. 6B is a schematic diagram of etching a conducting channel in a manufacturing method for a memory according to some embodiments of the present disclosure.

FIG. 7 is a schematic diagram of forming a source electrode in a manufacturing method for a memory according to some embodiments of the present disclosure.

FIG. 8 is a schematic diagram of a memory according to some embodiments of the present disclosure.

FIG. 9 is a schematic diagram of a substrate of a memory according to some embodiments of the present disclosure.

FIG. 10 is a schematic diagram of forming a conducting channel in a memory according to some embodiments of the present disclosure.

FIG. 11 is a first schematic diagram of forming a source electrode of a transistor in a memory according to some embodiments of the present disclosure.

FIG. 12 is a second schematic diagram of forming a source electrode of a transistor in a memory according to some embodiments of the present disclosure.

FIG. 13 is a schematic diagram of separating transistors from each other in a memory according to some embodiments of the present disclosure.

FIG. 14 is a schematic diagram of forming a trench accommodating a storage layer in a memory according to some embodiments of the present disclosure.

FIG. 15 is a schematic diagram of forming a storage layer in a memory according to some embodiments of the present disclosure.

FIG. 16 is a schematic diagram of forming an insulating layer for separating a storage layer in a memory according to some embodiments of the present disclosure.

FIG. 17 is a schematic diagram of forming a trench accommodating a gate electrode in a memory according to some embodiments of the present disclosure.

FIG. 18 is a schematic diagram of forming a gate electrode of a transistor in a memory according to some embodiments of the present disclosure.

FIG. 19 is a schematic diagram of forming a drain electrode of a transistor in a memory according to some embodiments of the present disclosure.

FIG. 20 is a schematic diagram of forming a bit line in a memory according to some embodiments of the present disclosure.

### DETAILED DESCRIPTION

Exemplary embodiments (examples of which are illustrated in the accompanying drawings) are elaborated below. The following description refers to the accompanying drawings, in which identical or similar elements in two drawings are denoted by identical reference numerals unless indicated otherwise. The exemplary implementation modes may take on multiple forms, and should not be taken as being limited to examples illustrated herein. Instead, by providing such implementation modes, embodiments herein may become more comprehensive and complete, and comprehensive concept of the exemplary implementation modes may be delivered to those skilled in the art. Implementations set forth in the following exemplary embodiments do not represent all implementations in accordance with the subject disclosure. Rather, they are merely examples of the apparatus and method in accordance with certain aspects herein as recited in the accompanying claims.

At present, higher and higher requirements on the storage performance and cell size of the memory are put forward in the market, which brings severe challenges to the design and manufacture of the memory.

The technical solution of the present disclosure can be applied to design and manufacture of a semiconductor memory, for example, a semiconductor memory such as a common DRAM. The common DRAM achieves storage of charges by using a capacitor, and the value of a binary bit is represented by a storage capacity of charges, that is, a memory cell can be used for representing a logical state of a bit. Due to the phenomena such as current leakage exists in a transistor, the stored charges are easily lost, which affects the stability of data storage. Therefore, periodic charging and discharging is required by the DRAM, and dynamic storage is achieved by refreshing storage data.

In consideration of a structure that a capacitor structure needs two capacitor plates, a dielectric layer and the like, a larger space size is required to be occupied, as a result, it is difficult to decrease the size of a single memory cell, and the overall size of the memory is also limited by this problem. Therefore, embodiments of the present disclosure provide a memory, transfer and storage of charges are achieved by using a storage layer communicated with a conducting channel of a transistor, and thus a 1T0C memory cell structure is achieved without a capacitor, thereby effectively reducing the size of the memory.

The technical solutions of the present disclosure are further described in detail with reference to the accompanying drawings and embodiments as follows.

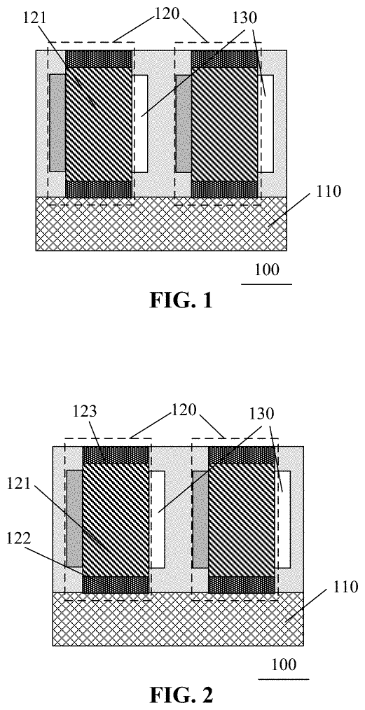

Embodiments of the present disclosure provide a memory. As illustrated in FIG. 1, the memory 100 includes: a substrate 110, a transistor array, and a storage layer 130.

The transistor array includes multiple transistors 120 on a surface of the substrate 110. Conducting channels 121 of the transistors 120 extend in a direction perpendicular to the surface of the substrate 110.

The storage layer 130 is disposed at a side of the conducting channel 121 of each transistor 120, communicated with the conducting channel 121 of the transistor 120, and configured to store charges and perform charge transfer with the communicated conducting channel.

Here, the substrate may be a semiconductor substrate made of a silicon material or other wafer materials. A device structure of the memory can be formed on the surface of the substrate through technological processes of semiconductor devices. For example, a layered graphical structure is formed on the surface of the substrate through the technological processes such as doping, photoetching, depositing, cleaning and the like, so as to form the semiconductor device.

In the embodiments of the present disclosure, multiple transistors are formed on the surface of the substrate, and the transistors are arranged on the surface of the substrate in pairs. Multiple pairs of transistors can be arranged in rows and columns to form transistor arrays to form a memory.

Here, the conducting channels of the transistors extend in a direction perpendicular to the surface of the substrate, less surface area of the substrate can be occupied compared with a transistor formed in parallel to the surface of the substrate, and the utilization rate of the area of the substrate is improved.

In the embodiments of the disclosure, the storage of the charges is achieved by the storage layer communicated with the conducting channel of each transistor, and the storage layer can perform charge transfer with the conducting channel, so as to achieve a change in a logical state of a memory cell. The storage layer may be made of a semiconductor material or a metal material, and may be used for storing electrons or holes. The storage layer is communicated with the conducting channel, and when a voltage is applied to the transistor, charges accumulate in the conducting channel and a potential difference is formed between the conducting channel and the storage layer, so that charge transfer occurs between the conducting channel and the storage layer, and the quantity of charges of the storage layer is changed. In this case, the charge transfer between the storage layer and the conducting channel is achieved through the control of the transistor, and charges are stored in the storage layer.

The storage layers are distributed on the side surfaces of the transistors and communicated with the conducting channels of the transistors, and the storage layers also extend in a direction perpendicular to the surface of the substrate, thereby occupying less surface area of the substrate.

The memory structure in the embodiments of the present disclosure not only saves a manufacturing space required for a capacitor structure in the memory, and further save the occupation of the surface area of the substrate by using a perpendicular form, thereby effectively increasing the number of memory cells in a unit area. The embodiments of the present disclosure further achieve the charge storage through the storage layer, which replaces the function of the original capacitor, achieves a 1T0C memory cell structure, and facilitates the development of a small size and a high integration degree of the memory.

In some embodiments, as illustrated in FIG. 2, a source electrode 122 of the transistor 120 is disposed at an end of the conducting channel 121 close to the surface of the substrate 110.

A drain electrode 123 of the transistor 120 is disposed at an end of the conducting channel 121 away from the surface of the substrate 110.

The transistor includes a source electrode, a gate electrode, and a drain electrode. A state switching of charge conduction or non-conduction between the source electrode and the drain electrode is achieved by voltage control of the gate electrode and a voltage difference between the source electrode and the drain electrode. In the embodiments of the present disclosure, an extension direction of the conducting channel of the transistor is a direction perpendicular to the surface of the substrate, and therefore, the source electrode and the drain electrode of the transistor are respectively disposed at two ends of the conducting channel, that is, one end is close to the surface of the substrate and the other one end is away from the surface of the substrate.

In this case, the structure of the transistor can effectively use a height space above the substrate, which saves the surface area of the surface of the substrate, so that more memory cells may be integrated on the surface of the substrate per unit area, thereby improving storage efficiency of the memory.

In some embodiments, a first insulating layer covers a periphery of the source electrode of the transistor. A height of the first insulating layer with respect to the surface of the substrate is higher than a height of the source electrode with respect to the surface of the substrate.

The periphery of the source electrode of the transistor may be covered with the first insulating layer, so as to achieve the function of protecting and separating the source electrode and the storage layer. The first insulating layer may be evenly distributed on the surface of the substrate at a certain thickness, the first insulating layer at this thickness may completely cover the source electrode of the transistor, and the height of the first insulating layer with respect to the surface of the substrate is higher than the height of the source electrode with respect to the surface of the substrate.

Here, the material of the first insulating layer may be materials such as silicon oxide and silicon nitride, and may also be an organic material and the like.

In some embodiments, a second insulating layer is provided at a side, communicated with the storage layer, of the transistor, the second insulating layer covers the storage layer, and the second insulating layer is communicated with the first insulating layer. In the embodiments of the present disclosure, the transistors may be separated from each other through the second insulating layer, and the second insulating layer may extend from a position where the first insulating layer is, i.e., a bottom of the conducting channel of the transistor, directly to a top of the conducting channel. Moreover, the second insulating layer is separated from the first insulating layer, and the storage layer is also separated from other transistors and other storage layers through the insulating layers.

In addition, since the first insulating layer covers the source electrode of the transistor, the first insulating layer is communicated with the second insulating layer, so as to form an overall insulating layer, so that the source electrode of the transistor and the storage layer are separated from each other, and are covered with the insulating layers, so as to reduce charge movement between the source electrode and the storage layer, thereby facilitating stably storing charges by the storage layer.

Here, the first insulating layer and the second insulating layer may be made of the same material, and may also be made of different materials.

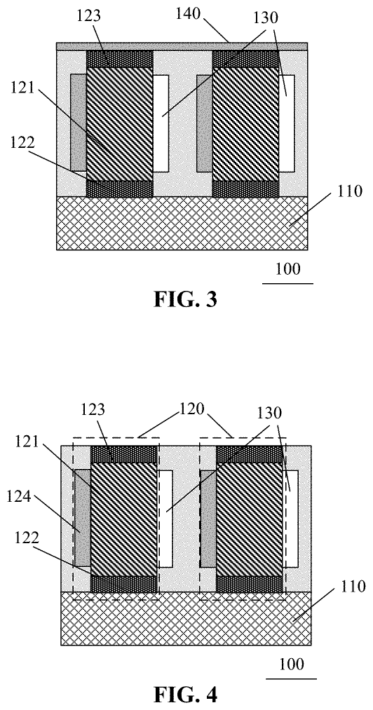

In some embodiments, as illustrated in FIG. 3, the memory may further include: at least one bit line 140, disposed at a side, away from the surface of the substrate 110, of the transistor 120, and connected to the drain electrode 123 of the transistor 120.

In the embodiments of the present disclosure, multiple transistors of the memory may be arranged to form a transistor array having a row-column structure. Each column of transistors can be connected through the bit line, thereby facilitating controlling data reading and writing of the whole column of transistors through the bit line.

The bit line may be a linear thin film made of a conductive material, is connected to the drain electrode of the transistor, and can transfer charges with the drain electrode of the transistor. The data reading and writing state of the transistor depends on the potential of the bit line. Therefore, a voltage can be applied to the bit line of the memory through an external circuit, so as to change the potential of the bit line.

In some embodiments, the bit line is communicated with the drain electrodes of the transistors disposed in the same column in the transistor array.

In the embodiments of the present disclosure, a bit line may cover multiple transistors, that is, the transistors disposed in the same column in the transistor array are controlled by the same bit line. In this case, accurate control of each transistor can be achieved through coordination of the bit line with a word line in the memory.

In some embodiments, as illustrated in FIG. 4, a gate electrode 124 of the transistor 120 is disposed at another side opposite to a side, communicated with the storage layer 130, of the conducting channel 121, and the conducting channel 121 of the transistor 120 is disposed between the gate electrode 124 and the storage layer 130. Since the conducting channel of the transistor in the embodiments of the present disclosure extends in a direction perpendicular to the surface of the substrate, charge flow between the source electrode and the drain electrode of the transistor is also in a direction in which the conducting channel extends. The gate electrode of the transistor controls conduction performance of the conducting channel from a side of the conducting channel, and the gate electrode of the transistor is disposed on the side surface of the conducting channel and is in parallel to the conducting channel.

The storage layer corresponding to the transistor is communicated with a side of the conducting channel of the transistor, and therefore, the gate electrode of the transistor is disposed at the other side of the conducting channel, and this side is opposite to the side where the storage layer is, so that the conducting channel of the transistor is disposed between the gate electrode and the storage layer.

In some embodiments, the gate electrode may include: a gate electrode oxide layer and a gate electrode conducting layer.

The gate electrode oxide layer is disposed between the gate electrode conducting layer and the conducting channel, or the gate electrode oxide layer wraps the gate electrode conducting layer and is connected to the conducting channel.

In the embodiments of the present disclosure, the gate electrode oxide layer is provided between the conducting channel of the transistor and the gate electrode conducting layer of the transistor, and configured to separate the gate electrode conducting layer from the conducting channel. In this case, the conducting performance of the conducting channel may be controlled through the field effect generated between the potential of the gate electrode conducting layer and the conducting channel. That is, the conduction or non-conduction state of the conducting channel may be switched through a voltage applied to the gate electrode conducting layer.

The gate electrode oxide layer and the gate electrode conducting layer may be formed into a two-layer structure parallel to the conducting channel, and the outer side of the gate electrode conducting layer may be isolated through an insulating material, so as to be independent from a gate electrode of an adjacent transistor. In addition, the gate electrode oxide layer may also wrap the gate electrode conducting layer, so that an inner side and an outer side of the gate electrode conducting layer are separated by the gate electrode oxide layer.

In some embodiments, the memory may further include: a gate electrode protective layer, covering a side, away from the surface of the substrate, of the gate electrode.

The gate electrode protective layer covers the upper part of the gate electrode and may be flush with the drain electrode of the transistor, so as to separate the gate electrode from the drain electrode, and separate the gate electrode from other structures on the top of the transistor, for example, the bit line.

The gate electrode protective layer may be made of insulating materials such as oxides or silicon nitride. Certainly, the gate electrode protective layer may also be a thin film made of the same material as the gate electrode oxide layer, and is communicated with the gate electrode oxide layer, so as to protect and separate the gate electrode conducting layer.

In some embodiments, the gate electrodes of the transistors disposed in the same row in the transistor array are communicated with each other, and the communicated gate electrodes are word lines of the same row of transistors.

In the embodiments of the present disclosure, the gate electrode of the transistor is shared by multiple transistors. That is, the gate electrode covers the conducting channels of multiple transistors from the side surfaces in a long-strip shape manner.

In this case, the transistors disposed in the same row are controlled by the same gate electrode, and this gate electrode is also a word line of this row of transistors.

In this case, for the whole memory, the word line and the bit line of the transistor array form a structure in which rows and columns are controlled separately, so that accurate read and write control for each transistor can be achieved.

Embodiments of the present disclosure further provide a manufacturing method for a memory. As illustrated in FIG. 5, the method includes as follows.

In block S101, a transistor array including multiple transistors is formed on a surface of a substrate, and conducting channels of the transistors extend in a direction perpendicular to the surface of the substrate.

In block S102, a storage layer is formed on a side surface of each transistor in the direction perpendicular to the surface of the substrate. The storage layer is communicated with the transistor, and configured to store charges and perform charge transfer with the communicated conducting channel.

Here, multiple transistors are formed on the surface of the substrate, and may be synchronously formed on the surface of the substrate to form a transistor array having a row and column structure.

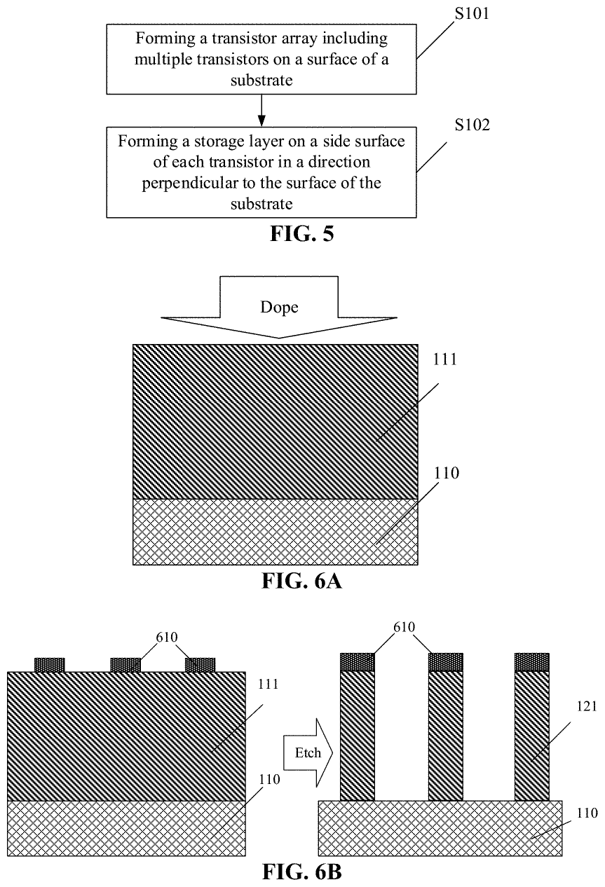

In the embodiments of the present disclosure, treatment such as doping and ion injection can be performed on the surface of the substrate at a certain thickness, so that the substrate at a certain thickness has higher conductive performance. In this case, a doped semiconductor layer on the surface of the substrate is as illustrated in FIG. 6A, the upper layer of a substrate 110 is a treated semiconductor layer, and may be called as an active layer 111 here.

Then multiple conducting channels having row and row distribution can be formed through processes such as photoetching. As illustrated in FIG. 6B, a process of forming conducting channels 121 may include: covering a surface of the active layer with a mask layer 610, and then removing a semiconductor material of a part of the active layer through graphical lighting, etching and other processes, the reserved part being the conducting channels 121 of multiple transistors. The bottom of the remaining substrate is the substrate of the memory, used as a carrier of the transistor array, and configured to provide a ground potential and connected to the source electrode or the drain electrode of the transistor. In addition, the structures such as the source electrode, the gate electrode, and the drain electrode of the transistor can further respectively be formed at adjacent positions of the conducting channel of the transistor so as to form the transistor array of the memory. In this case, the formed conducting channel extends perpendicularly with respect to the surface of the substrate, and therefore, less surface area of the substrate can be occupied, and the integration degree of the memory is improved.

A storage layer may be correspondingly formed for each transistor, the storage layer may be communicated with the conducting channel of the transistor, and therefore, a semiconductor material or a metal material used in the storage layer may cover the side surface of the conducting channel of the transistor to form a thin film.

In this case, the transistor array is evenly distributed, and the storage layer corresponding to each transistor may be formed. In the process of using the memory, charge flow and charge storage in the corresponding storage layer may be achieved through the control of each transistor. For the whole memory, read/write and storage functions of data may be achieved through the control of transistors at different positions.

In some embodiments, the operation of forming the storage layer on the side surface of each transistor in the direction perpendicular to the surface of the substrate may include: forming a trench at a side of the conducting channel of the transistor; depositing a semiconductor material or a metal material in the trench to cover a side wall and a bottom of the trench; and etching to remove the semiconductor material or metal material on the bottom of the trench to form the storage layer.

In the process of forming the conducting channel of the transistor on the substrate, the semiconductor material of the active layer between the transistors needs to be removed, so that each conducting channel is perpendicular to the bottom layer of the substrate, and the trenches are formed between the conducting channels through the process. Therefore, the storage layer may be formed in the trench at the side of the conducting channel of each transistor, and covers the side surface of the conducting channel.

Exemplarily, the semiconductor material or the metal material, including materials such as single crystalline silicon (Si), germanium (Ge), silicon-germanium (Si—Ge), aluminum-antimony (Al—Sb), gallium-antimony (Ga—Sb) or the like is deposited on the trench through the approaches including physical vapor deposition (PVD) and chemical vapor deposition (CVD) and the like, so that the semiconductor material or the metal material may cover the side of the conducting channel of the transistor to form the storage layer.

In this case, the transistor array is evenly distributed, and the corresponding storage layers are formed. In the process of using the memory, charge flow and charge storage in the corresponding storage layer may be achieved through the control for each transistor. For the whole memory, the read/write and storage functions of data may be achieved through the control of the transistors at different positions.

In some embodiments, the operation of forming the transistor array including multiple transistors on the surface of the substrate may include: forming multiple conducting channels, perpendicular to the surface of the substrate, on the surface of the substrate; forming source electrodes of the multiple transistors at an end, close to the surface of the substrate, of each conducting channel; and forming drain electrodes of the multiple transistors at an end, away from the surface of the substrate, of each conducting channel.

The transistor includes a source electrode, a gate electrode, and a drain electrode. A state switching of charge conduction or non-conduction between the source electrode and the drain electrode is achieved by voltage control of the gate electrode and a voltage difference between the source electrode and the drain electrode. In the embodiments of the present disclosure, an extension direction of the conducting channel of the transistor is a direction perpendicular to the surface of the substrate, and therefore, the source electrode and the drain electrode of the transistor are respectively disposed at two ends of the conducting channel, that is, one end is close to the surface of the substrate and the other one end is away from the surface of the substrate.

In the embodiments of the present disclosure, the source electrode of the transistor may be first formed at the end, close to the surface of the substrate, of the conducting channel after the conducting channel is formed. In this case, the source electrode is communicated with the substrate. Therefore, the source electrode may be grounded through the substrate. The drain electrode of the transistor may be then formed at the end, away from the surface of the substrate, of the conducting channel. In this case, charge transfer of the transistor is performed along a conductive path formed from the source electrode through the conducting channel to the drain electrode.

It should be noted that the order of forming the structures such as the source electrode, the drain electrode, and the gate electrode of the conducting channel, and the storage layer is not defined here. The source electrode, the drain electrode, and the gate electrode of the conducting channel may be formed before the storage layer is formed; the storage layer may be formed after the source electrode of the conducting channel is formed, and then the drain electrode, the gate electrode and the like are formed. In practical applications, the forming order may be considered comprehensively according to production planning, the shape of each layer of a photomask, the characteristics of each layer of material, and device parameter requirements of the process and the like.

In some embodiments, the operation of forming conducting channels, perpendicular to the surface of the substrate, on the surface of the substrate may include: doping on a silicon material substrate to form an active layer; and performing graphical etching on the active layer to form the conducting channels perpendicular to the surface of the substrate.

The substrate may be a semiconductor substrate made of a silicon material or other wafer materials. In the process of forming the transistor, the semiconductor material at a certain thickness of the surface layer of the substrate may be first doped, such as N-type doping or P-type doping. For example, doping or ion injection may be performed by trivalent or pentavalent ions such as phosphorus or boron ions, so that a P-type semiconductor or an N-type semiconductor is formed on the surface layer of the substrate. The purpose is to improve the conductive performance of the semiconductor material, so that the semiconductor material may form the conducting channel of the transistor.

Then graphical etching is performed, the semiconductor material at the position other than the position required for forming the conducting channel is removed, and the semiconductor material of the reserved part forms the conducting channel. Here, a pattern reserved by the graphical etching is a shape of the conducting channel, which may be of a cylinder having a shape such as a square section, a rectangular section, a rhombus section, or a round section, and these cylinders form the conducting channels of the transistors.

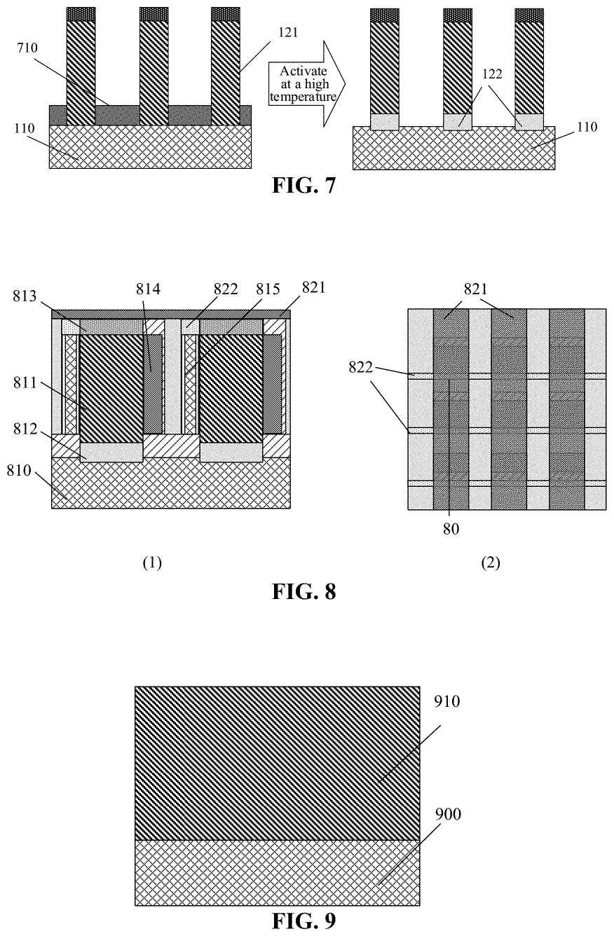

In some embodiments, as illustrated in FIG. 7A, the operation of forming the source electrode 122 of the transistor 120 at the end, close to the surface of the substrate 110, of the conducting channel 121 may include: depositing a heavily-doped dielectric layer 710 on the surface of the substrate; and activating the heavily-doped dielectric layer 710 at a high temperature, and forming the source electrode 122 at the end, close to the surface of the substrate 110, of the conducting channel 121.

Here, the heavily-doped dielectric layer may be made of a semiconductor material containing the doped iron having polarity opposite to that of the conducting channel. For example, the conducting channel is N-type doping, then the heavily-doped dielectric layer is P-type doping. The conducting channel is P-type doping, then the heavily-doped dielectric layer is N-type doping.

In this case, conductive ions in the heavily-doped dielectric layer are activated through high temperature activation, and thus are transferred to the conducting channel, so that ions having opposite polarity are re-injected at the end portion, close to the surface of the substrate, of the conducting channel, so as to form the source electrode of the transistor.

After the high temperature activation and forming the source electrode at the bottom of the conducting channel, the heavily-doped dielectric layer may be removed by an etching method. In order to prevent a residual heavily-doped dielectric layer material on the surface of the substrate, a part of the substrate may be over-etched in the etching process, so that a part of the source electrode of the transistor is embedded in the substrate, and the other part is exposed on the substrate.

In some embodiments, the operation of forming drain electrodes of the transistors at the end, away from the surface of the substrate, of each conducting channel may include: epitaxially growing a single crystalline silicon layer at the end, away from the surface of the substrate, of each conducting channel; and performing ion injection or doping on the single crystalline silicon layer to form the drain electrode.

When the drain electrodes are formed, the single crystalline silicon may be epitaxially grown at the end, away from the surface of the substrate, of each conducting channel of the transistor, and doping or ion injection may be further performed to form the P-type or N-type semiconductor. It should be noted that the doping polarity for forming the drain electrode and the polarity of the conducting channel are also opposite, so as to form a transistor having a PNP or NPN structure.

In some embodiments, the method may further include: forming a first insulating layer at the periphery of the source electrode of each transistor; herein a height of the first insulating layer with respect to the surface of the substrate is higher than a height of the source electrode with respect to the surface of the substrate.

After the source electrode of the transistor is formed, the storage layer corresponding to the transistor may further be formed on the side surface of the conducting channel of the transistor. However, since the storage layer and the source electrode cannot be communicated, the source electrode of the transistor may be isolated and protected here by forming the first insulating layer covering the source electrode, and then the storage layer corresponding to the transistor is formed.

Here, the material of the first oxide layer may be an insulating thin film formed by silicon oxide, silicon nitride or other organic materials.

In some embodiments, the method may further include: forming a second insulating layer at a side, communicated with the storage layer, of the transistor; herein the second insulating layer covers the storage layer, and the second insulating layer is communicated with the first insulating layer.

Here, after the storage layer corresponding to each transistor is formed, the second insulating layer may be formed between the transistors, and the second insulating layer is communicated with the first insulating layer. In this case, the second insulating layer may wrap the storage layer and the transistor, so as to prevent charge leakage, and improve storage performance.

The second insulating layer and the first insulating layer may be made of the same material, and may also be made of different materials. Moreover, the process of forming the second insulating layer may achieve the function of separating the storage layers of the transistors by depositing the insulating material to fill the trenches between the transistors.

In some embodiments, the method may further include: forming at least one bit line at a side, away from the surface of the substrate, of the transistor; herein the bit line is connected to the drain electrode of the transistor.

In the embodiments of the present disclosure, the trench between the transistors is filled with the second oxide layer, so that the end, away from the surface of the substrate, of the transistor is within an approximate plane. In this case, the metal material, the semiconductor material having high conductive performance or other materials may be coated on the uppermost layer to form a conducting layer.

Then the excess conductive material is removed from the conducting layer through graphical etching, and a linear conductive material is reserved to form the bit line.

Here, the bit line is connected to the drain electrode of the transistor, so as to perform charge transfer.

In some embodiments, the operation of forming the transistor array including multiple transistors on the surface of the substrate may further include: forming a gate electrode of the transistor at another side opposite to a side, communicated with the storage layer, of the conducting channel, herein the conducting channel of the transistor is disposed between the gate electrode and the storage layer.

Since the gate electrode of the transistor may be formed at another side opposite to a side of the conducting channel of the transistor where the storage layer is formed, the process of forming the gate electrode may be performed either before or after the formation of the storage layer.

After the gate electrode and the storage layer are formed, each transistor and a corresponding storage layer have the same structure, and are neatly arranged on the surface of the substrate to form an array structure of the memory cell.

In some embodiments, the operation of forming the gate electrode of the transistor at the another side opposite to the side, communicated with the storage layer, of the conducting channel may include: forming a gate electrode oxide layer communicated with the conducting channel at the another side of the conducting channel; and forming a gate electrode conducting layer communicated with the gate electrode oxide layer at a side of the gate electrode oxide layer, herein the gate electrode oxide layer is disposed between the gate electrode conducting layer and the conducting channel; or the gate electrode oxide layer wraps the gate electrode conducting layer and is connected to the conducting channel.

The gate electrode of the transistor includes the gate electrode oxide layer and the gate electrode conducting layer. The gate electrode oxide layer may be first formed at a side of the conducting channel of the transistor, and then the gate electrode conducting layer is formed. The gate electrode oxide layer may also be first formed, the trench is formed by etching the middle of the gate electrode oxide layer, and then the gate electrode conducting layer is formed in the trench, so that the gate electrode conducting layer is wrapped by the gate electrode oxide layer.

In some embodiments, the method may further include: forming a gate electrode protective layer covering the gate at an end, away from the surface of the substrate, of the gate electrode.

Since the top of the gate electrode conducting layer, i.e., the end away from the surface of the substrate may be exposed, in order to protect the gate electrode conducting layer and enable same not to be interfered by the outside, the insulating gate electrode protective layer may cover the gate.

The gate electrode protective layer may be made of insulating materials such as oxides, silicon nitride or the like. Certainly, the gate electrode protective layer may also be a thin film made of the same material as the gate electrode oxide layer, and is communicated with the gate electrode oxide layer, so as to protect and separate the gate electrode conducting layer.

In some embodiments, the operation of forming the gate electrode of the transistor at the another side opposite to the side, communicated with the storage layer, of the conducting channel may include: forming a penetrated trench at a side of the same row of transistors in the transistor array; and forming the gate electrodes communicated with the same row of transistors in the trench, herein the gate electrodes are word lines of the same row of transistors.

In the process of forming the gate electrode, a penetrated trench may be formed at the another side, opposite to the storage layer, of the conducting channel of the transistor, so as to form a gate electrode shared by a row of transistors. In this case, the gate electrode shared by this row of transistors forms a corresponding word line.

The embodiments of the present disclosure further provide the following examples.

As illustrated in FIG. 8, embodiments of the present disclosure provide a schematic diagram of a memory, that is, a DRAM having a perpendicular channel and having no capacitor structure, i.e., a 1T0C DRAM. As illustrated in part (1) of a sectional view of a memory illustrated in FIG. 8, a conducting channel 811 of a transistor is perpendicular to a surface of a substrate 810, a source electrode 812 is disposed at an end close to the surface of the substrate 810, and a drain electrode 813 is disposed at an end away from the surface of the substrate 810. A storage layer 814 is provided at a side of each transistor, and is communicated with the conducting channel 811 of the transistor. In addition, a gate electrode 815 of the transistor is disposed at a relative outer side of the transistor. An insulating material is filled between the transistors so as to separate the transistors. Since no capacitor is needed, each memory cell (the transistor and the corresponding storage layer) may be decreased to 2F2 in size, (F is the smallest shape size of the memory cell, and F2 represents a unit area). Moreover, since the conducting channel 811 extends in a direction perpendicular to the surface of the substrate 810, the length of the conducting channel 811 may be increased without occupying too much surface area of the substrate 810.

A top view of the memory is as illustrated in part (2) in FIG. 8, the conductive materials cover the tops of the transistors and are communicated with the whole column of transistors, so as to form a bit line 821. The gate electrodes of the transistors penetrate through the whole row of transistors to form a word line, part (2) of the top view in FIG. 8 does not show the gate electrodes, but gate electrode protective layers 822 at a position where the tops of the gate electrodes and the word line are may be seen. A section corresponding to part (1) of the sectional view in FIG. 8 is disposed at a straight line 80 corresponding to part (2) of the top view.

The method for forming the structure includes as follows.

In block 1, as illustrated in FIG. 9, P-type doping or N-type doping is performed at a certain thickness of a silicon substrate 900 to form an active layer 910.

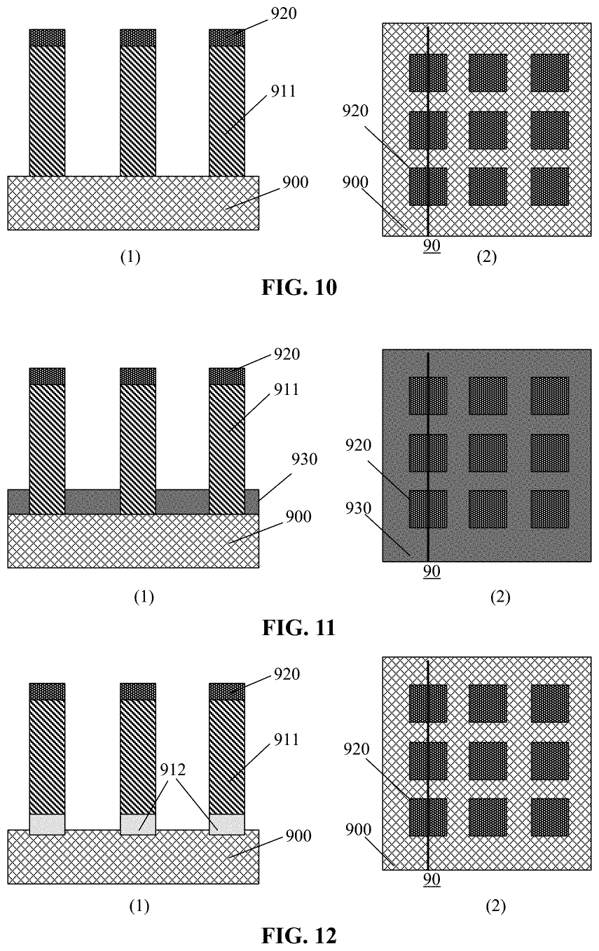

In block 2, as illustrated in FIG. 10, the active layer 910 is covered with a mask layer 920, and subjected to graphical etching, the active layer other than the conducting channel is removed, and the remaining semiconductor structure is a conducting channel 911. The conducting channel 911 may be of different shapes such as a square and a diamond. The mask layer 920 may be made of silicon nitride. Part (1) in FIG. 10 is a sectional view, and part (2) is a top view, herein a black line 90 represents a sectional position of part (1).

In block 3, as illustrated in FIG. 11, a heavily-doped dielectric layer 930 is deposited at a gap between the conducting channels on the surface of the substrate, and a doped ion is of a type opposite to that in an active area. Part (1) in FIG. 11 is a sectional view, and part (2) is a top view, herein the black line 90 represents a sectional position of part (1).

In block 4, as illustrated in FIG. 12, high temperature activation is performed after the heavily-doped dielectric layer is deposited, so that the source electrode 912 or the drain electrode is formed on a bottom of the active area, i.e., a bottom of the conducting channel 911, and then the heavily-doped dielectric layer may be removed by etching. Here, in order to completely remove the heavily-doped dielectric layer, a part of the substrate may be over-etched. Part (1) in FIG. 12 is a sectional view, and part (2) is a top view, herein the black line 90 represents a sectional position of part (1).

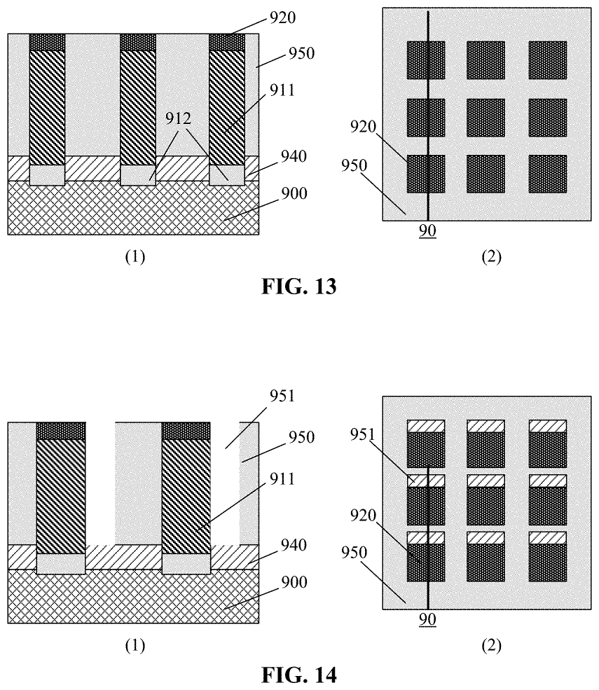

In block 5, as illustrated in FIG. 13, an oxide layer 940 is deposited on the surface of the substrate, and a surface of the oxide layer 940 may be slightly higher than a surface of the source electrode 912, so as to effectively isolate the source. Then an insulating medium 950 may fill the upper part of the oxide layer 940. The material of the insulating medium layer 950 may be inorganic materials such as silicon oxide or silicon nitride, and may also be an organic insulating material. Part (1) in FIG. 13 is a sectional view, and part (2) is a top view, herein the black line 90 represents a sectional position of part (1).

In block 6, as illustrated in FIG. 14, graphical etching is performed, a trench 951 or a hole structure is formed in the insulating medium 950 at a side of the active area, so as to expose the conducting channel 911 of the transistor. The oxide layer 940 is used as an etch stop layer, so as to prevent etching and exposing the source. Part (1) in FIG. 14 is a sectional view, and part (2) is a top view, herein the black line 90 represents a sectional position of part (1).

In block 7, as illustrated in FIG. 15, at least one of a semiconductor material layer or a metal material layer is formed in the trench 951. A semiconductor layer may be a Si layer, and the semiconductor material may include at least one of Ge, Si—Ge, Al—Sb, or Ga—Sb, a valence band of the semiconductor material layer is higher than that of the active area, quantum dots may further be included in the semiconductor for storing electrons, that is, a storage layer 960 communicated with the conducting channel 911 is formed. Part (1) in FIG. 15 is a sectional view, and part (2) is a top view, herein the black line 90 represents a sectional position of part (1).

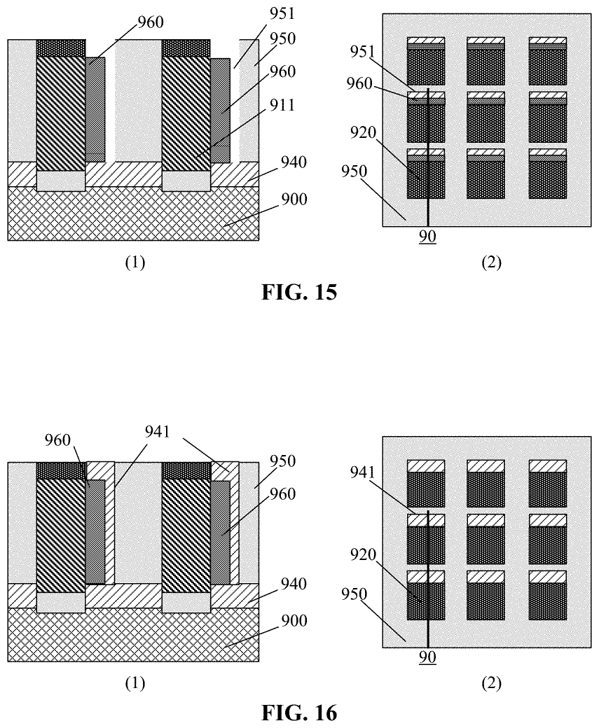

In block 8, as illustrated in FIG. 16, the trench 951 is filled with the oxide layer 941, so that the oxide layer 940 and the oxide layer 941 are communicated, and wrap the storage layer 960 corresponding to the transistor. Part (1) in FIG. 16 is a sectional view, and part (2) is a top view, herein the black line 90 represents a sectional position of part (1).

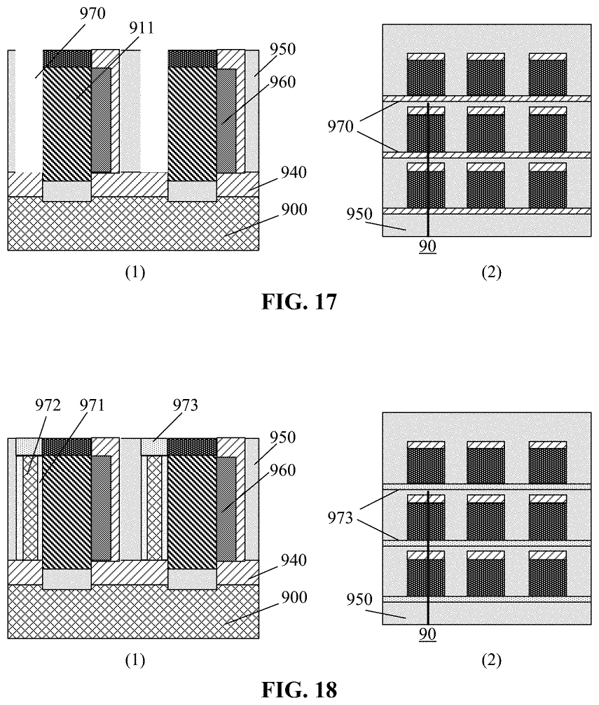

In block 9, as illustrated in FIG. 17, graphical etching is performed, a trench 970 is open in an isolation layer of the other side of the conducting channel 911, an active area is exposed, and the oxide layer 940 is an etch stop layer, so as to prevent the trench from exposing the source. Part (1) in FIG. 17 is a sectional view, and part (2) is a top view, herein the black line 90 represents a sectional position of part (1).

In block 10, as illustrated in FIG. 18, a gate electrode oxide layer 971 and a gate electrode metal layer 972 are deposited in the trench 970, and etched back to a position of an active area level, and a gate electrode protective layer 973 is filled. Part (1) in FIG. 18 is a sectional view, and part (2) is a top view, herein the black line 90 represents a sectional position of part (1).

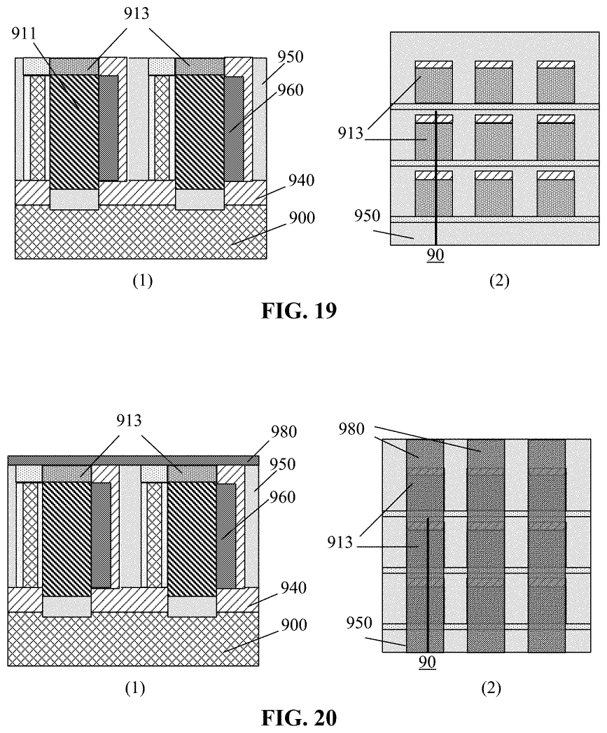

In block 11, as illustrated in FIG. 19, a mask layer of the conducting channel 911, i.e., the top of the active layer is removed, the single crystalline silicon layer is epitaxially grown, and then a drain electrode 913 of the transistor is formed through ion injection or doping. Part (1) in FIG. 19 is a sectional view, and part (2) is a top view, herein the black line 90 represents a sectional position of part (1).

In block 12, as illustrated in FIG. 20, the top of the transistor structure forms a conductive layer, and then a bit line 980 connected to the drain electrode 913 is formed through the graphical etching. Part (1) in FIG. 20 is a sectional view, and part (2) is a top view, herein the black line 90 represents a sectional position of part (1).

The various device components, modules, units, blocks, or portions may have modular configurations, or are composed of discrete components, but nonetheless can be referred to as “modules” in general. In other words, the “components,” “modules,” “blocks,” “portions,” or “units” referred to herein may or may not be in modular forms.

In the present disclosure, the terms “installed,” “connected,” “coupled,” “fixed” and the like shall be understood broadly, and can be either a fixed connection or a detachable connection, or integrated, unless otherwise explicitly defined. These terms can refer to mechanical or electrical connections, or both. Such connections can be direct connections or indirect connections through an intermediate medium. These terms can also refer to the internal connections or the interactions between elements. The specific meanings of the above terms in the present disclosure can be understood by those of ordinary skill in the art on a case-by-case basis.

In the description of the present disclosure, the terms “one embodiment,” “some embodiments,” “example,” “specific example,” or “some examples,” and the like can indicate a specific feature described in connection with the embodiment or example, a structure, a material or feature included in at least one embodiment or example. In the present disclosure, the schematic representation of the above terms is not necessarily directed to the same embodiment or example.

Moreover, the particular features, structures, materials, or characteristics described can be combined in a suitable manner in any one or more embodiments or examples. In addition, various embodiments or examples described in the specification, as well as features of various embodiments or examples, can be combined and reorganized.

In some embodiments, the control and/or interface software or app can be provided in a form of a non-transitory computer-readable storage medium having instructions stored thereon is further provided. For example, the non-transitory computer-readable storage medium can be a ROM, a CD-ROM, a magnetic tape, a floppy disk, optical data storage equipment, a flash drive such as a USB drive or an SD card, and the like.

Implementations of the subject matter and the operations described in this disclosure can be implemented in digital electronic circuitry, or in computer software, firmware, or hardware, including the structures disclosed herein and their structural equivalents, or in combinations of one or more of them. Implementations of the subject matter described in this disclosure can be implemented as one or more computer programs, i.e., one or more portions of computer program instructions, encoded on one or more computer storage medium for execution by, or to control the operation of, data processing apparatus.

Alternatively, or in addition, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer storage medium can be, or be included in, a computer-readable storage device, a computer-readable storage substrate, a random or serial access memory array or device, or a combination of one or more of them.

Moreover, while a computer storage medium is not a propagated signal, a computer storage medium can be a source or destination of computer program instructions encoded in an artificially-generated propagated signal. The computer storage medium can also be, or be included in, one or more separate components or media (e.g., multiple CDs, disks, drives, or other storage devices). Accordingly, the computer storage medium can be tangible.

The operations described in this disclosure can be implemented as operations performed by a data processing apparatus on data stored on one or more computer-readable storage devices or received from other sources.

The devices in this disclosure can include special purpose logic circuitry, e.g., an FPGA (field-programmable gate array), or an ASIC (application-specific integrated circuit). The device can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The devices and execution environment can realize various different computing model infrastructures, such as web services, distributed computing, and grid computing infrastructures.

A computer program (also known as a program, software, software application, app, script, or code) can be written in any form of programming language, including compiled or interpreted languages, declarative or procedural languages, and it can be deployed in any form, including as a stand-alone program or as a portion, component, subroutine, object, or other portion suitable for use in a computing environment. A computer program can, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more portions, sub-programs, or portions of code). A computer program can be deployed to be executed on one computer or on multiple computers that are located at one site or distributed across multiple sites and interconnected by a communication network.

The processes and logic flows described in this disclosure can be performed by one or more programmable processors executing one or more computer programs to perform actions by operating on input data and generating output. The processes and logic flows can also be performed by, and apparatus can also be implemented as, special purpose logic circuitry, e.g., an FPGA, or an ASIC.

Processors or processing circuits suitable for the execution of a computer program include, by way of example, both general and special purpose microprocessors, and any one or more processors of any kind of digital computer. Generally, a processor will receive instructions and data from a read-only memory, or a random-access memory, or both. Elements of a computer can include a processor configured to perform actions in accordance with instructions and one or more memory devices for storing instructions and data.

Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device (e.g., a universal serial bus (USB) flash drive), to name just a few.

Devices suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

To provide for interaction with a user, implementations of the subject matter described in this specification can be implemented with a computer and/or a display device, e.g., a VR/AR device, a head-mount display (HMD) device, a head-up display (HUD) device, smart eyewear (e.g., glasses), a CRT (cathode-ray tube), LCD (liquid-crystal display), OLED (organic light emitting diode), or any other monitor for displaying information to the user and a keyboard, a pointing device, e.g., a mouse, trackball, etc., or a touch screen, touch pad, etc., by which the user can provide input to the computer.

Implementations of the subject matter described in this specification can be implemented in a computing system that includes a back-end component, e.g., as a data server, or that includes a middleware component, e.g., an application server, or that includes a front-end component, e.g., a client computer having a graphical user interface or a Web browser through which a user can interact with an implementation of the subject matter described in this specification, or any combination of one or more such back-end, middleware, or front-end components.

The components of the system can be interconnected by any form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

While this specification contains many specific implementation details, these should not be construed as limitations on the scope of any claims, but rather as descriptions of features specific to particular implementations. Certain features that are described in this specification in the context of separate implementations can also be implemented in combination in a single implementation. Conversely, various features that are described in the context of a single implementation can also be implemented in multiple implementations separately or in any suitable subcombination.

Moreover, although features can be described above as acting in certain combinations and even initially claimed as such, one or more features from a claimed combination can in some cases be excised from the combination, and the claimed combination can be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing can be advantageous. Moreover, the separation of various system components in the implementations described above should not be understood as requiring such separation in all implementations, and it should be understood that the described program components and systems can generally be integrated together in a single software product or packaged into multiple software products.

As such, particular implementations of the subject matter have been described. Other implementations are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain implementations, multitasking or parallel processing can be utilized.

It is intended that the specification and embodiments be considered as examples only. Other embodiments of the disclosure will be apparent to those skilled in the art in view of the specification and drawings of the present disclosure. That is, although specific embodiments have been described above in detail, the description is merely for purposes of illustration. It should be appreciated, therefore, that many aspects described above are not intended as required or essential elements unless explicitly stated otherwise.

Various modifications of, and equivalent acts corresponding to, the disclosed aspects of the example embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

It should be understood that “a plurality” or “multiple” as referred to herein means two or more. “And/or,” describing the association relationship of the associated objects, indicates that there may be three relationships, for example, A and/or B may indicate that there are three cases where A exists separately, A and B exist at the same time, and B exists separately. The character “/” generally indicates that the contextual objects are in an “or” relationship.

In the present disclosure, it is to be understood that the terms “lower,” “upper,” “under” or “beneath” or “underneath,” “above,” “front,” “back,” “left,” “right,” “top,” “bottom,” “inner,” “outer,” “horizontal,” “vertical,” and other orientation or positional relationships are based on example orientations illustrated in the drawings, and are merely for the convenience of the description of some embodiments, rather than indicating or implying the device or component being constructed and operated in a particular orientation. Therefore, these terms are not to be construed as limiting the scope of the present disclosure.

Moreover, the terms “first” and “second” are used for descriptive purposes only and are not to be construed as indicating or implying a relative importance or implicitly indicating the number of technical features indicated. Thus, elements referred to as “first” and “second” may include one or more of the features either explicitly or implicitly. In the description of the present disclosure, “a plurality” indicates two or more unless specifically defined otherwise.

In the present disclosure, a first element being “on” a second element may indicate direct contact between the first and second elements, without contact, or indirect geometrical relationship through one or more intermediate media or layers, unless otherwise explicitly stated and defined. Similarly, a first element being “under,” “underneath” or “beneath” a second element may indicate direct contact between the first and second elements, without contact, or indirect geometrical relationship through one or more intermediate media or layers, unless otherwise explicitly stated and defined.

It should be noted that, the terms “include”, “comprise” or any other variants thereof herein are intended to cover non-exclusive inclusion, so that a process, method, article or apparatus that includes a series of elements includes not only those elements, but also other elements that are not explicitly listed or elements inherent to the process, method, article, or apparatus. If no more limitations is made, an element defined by a phrase “including one . . . ” does not exclude that there are other same elements in the process, method, article or apparatus including the elements.

It should be understood that the device and method disclosed in several embodiments provided in the present disclosure may be implemented in other manners. The device embodiments described above are merely exemplary. For example, the unit division is merely logical function division and may be actually implemented in other division manners. For example, a plurality of units or components may be combined or integrated into another system, or some features may be ignored or not performed. In addition, the displayed or discussed mutual couplings or direct couplings or communication connections among the components may be implemented through some interfaces. The indirect couplings or communication connections between the devices or units may be electrical, mechanical, or in other forms.

The units described as separate components may or may not be physically separate, and the components displayed as units may or may not be physical units both, may be disposed at one position, or may be distributed on a plurality of network units. Some or all of the units may be selected according to actual needs to achieve the objectives of the solutions of the embodiments.

In addition, the functional units in the embodiments of the present disclosure may be integrated into a processing unit, or each of the units may exist as an independent unit, or two or more units are integrated into one unit, and the integrated unit may be implemented in the form of hardware, or may also be implemented in the form of a hardware and software functional unit.

Some other embodiments of the present disclosure can be available to those skilled in the art upon consideration of the specification and practice of the various embodiments disclosed herein. The present application is intended to cover any variations, uses, or adaptations of the present disclosure following general principles of the present disclosure and include the common general knowledge or conventional technical means in the art without departing from the present disclosure. The specification and examples can be shown as illustrative only, and the true scope and spirit of the disclosure are indicated by the following claims.

### INDUSTRIAL APPLICABILITY

Embodiments of the present disclosure provide a memory and a manufacturing method thereof. The manufacturing method is applied to industrial production of memories. According to the technical solutions of the embodiments of the present disclosure, storage of charges and charge transfer to conducting channels are achieved by using a storage layer disposed on a side surface of the transistor, thus a capacitor-free memory cell is achieved, and the occupied area and complexity of each memory cell are saved. Moreover, an approach of extending in a direction perpendicular to a surface of a substrate is used in the design of the transistor and the storage layer, a structural space in a perpendicular direction is effectively used, and the surface area of the memory is saved, thereby facilitating the design and manufacture of a miniaturized and highly integrated memory.

What is claimed is:

1. A memory, comprising:
a substrate;
a transistor array comprising multiple transistors on a surface of the substrate; conducting channels of the transistors extending in a direction perpendicular to the surface of the substrate; and
a storage layer, disposed at a side of the conducting channel of each transistor, communicated with the conducting channel of the transistor, and configured to store charges and perform charge transfer with the communicated conducting channel.

2. The memory of claim 1, wherein a source electrode of the transistor is disposed at an end, close to the surface of the substrate, of the conducting channel; and
a drain electrode of the transistor is disposed at an end, away from the surface of the substrate, of the conducting channel.

3. The memory of claim 2, wherein a first insulating layer covers a periphery of the source electrode of the transistor; and a height of the first insulating layer with respect to the surface of the substrate is higher than a height of the source electrode with respect to the surface of the substrate.

4. The memory of claim 3, wherein a second insulating layer is provided at a side, communicated with the storage layer, of the transistor, and the second insulating layer covers the storage layer and is communicated with the first insulating layer.

5. The memory of claim 2, further comprising:
at least one bit line, which is disposed at a side, away from the surface of the substrate, of the transistor, and is connected to the drain electrode of the transistor;
wherein the bit line is communicated with the drain electrodes of the transistors disposed in a same column in the transistor array.

6. The memory of claim 1, wherein a gate electrode of the transistor is disposed at another side opposite to the storage layer communicated with the conducting channel, and the conducting channel of the transistor is disposed between the gate electrode and the storage layer.

7. The memory of claim 6, wherein the gate electrode comprises: a gate electrode oxide layer and a gate electrode conducting layer;
wherein the gate electrode oxide layer is disposed between the gate electrode conducting layer and the conducting channel; or
the gate electrode oxide layer wraps the gate electrode conducting layer and is connected to the conducting channel.

8. The memory of claim 7, further comprising:
a gate electrode protective layer, covering a side, away from the surface of the substrate, of the gate electrode.

9. The memory of claim 6, wherein the gate electrodes of the transistors disposed in a same row in the transistor array are communicated with each other, and the communicated gate electrodes are word lines of a same row of transistors.

10. A manufacturing method for a memory, comprising:
forming a transistor array comprising multiple transistors on a surface of a substrate, wherein conducting channels of the transistors extend in a direction perpendicular to the surface of the substrate; and
forming a storage layer on a side surface of each transistor in the direction perpendicular to the surface of the substrate, wherein the storage layer is communicated with the transistor, and configured to store charges and perform charge transfer with the communicated conducting channel.

11. The method of claim 10, wherein the forming the storage layer on the side surface of each transistor in the direction perpendicular to the surface of the substrate comprises:
forming a trench at a side of the conducting channel of the transistor;
depositing a semiconductor material or a metal material in the trench to cover a side wall and a bottom of the trench; and
etching to remove the semiconductor material or metal material on the bottom of the trench to form the storage layer.

12. The method of claim 10, wherein the forming the transistor array comprising multiple transistors on the surface of the substrate comprises:
forming multiple conducting channels, perpendicular to the surface of the substrate, on the surface of the substrate;
forming source electrodes of the multiple transistors at an end, close to the surface of the substrate, of each conducting channel; and
forming drain electrodes of the multiple transistors at an end, away from the surface of the substrate, of each conducting channel.

13. The method of claim 12, wherein the forming the multiple conducting channels, perpendicular to the surface of the substrate, on the surface of the substrate comprises:
doping on a silicon material substrate to form an active layer; and
performing graphical etching on the active layer to form the conducting channels perpendicular to the surface of the substrate;
wherein the forming the source electrodes of the multiple transistors at the end, close to the surface of the substrate, of each conducting channel comprises:
depositing a heavily-doped dielectric layer on the surface of the substrate; and
activating the heavily-doped dielectric layer at a high temperature, and forming the source electrodes at the end, close to the surface of the substrate, of each conducting channel;
wherein the forming the drain electrodes of the multiple transistors at the end, away from the surface of the substrate, of each conducting channel comprises:
epitaxially growing a single crystalline silicon layer at the end, away from the surface of the substrate, of each conducting channel; and
performing ion injection or doping on the single crystalline silicon layer to form the drain electrode.

14. The method of claim 12, further comprising:
forming a first insulating layer at a periphery of the source electrode of each transistor; wherein a height of the first insulating layer with respect to the surface of the substrate is higher than a height of the source electrode with respect to the surface of the substrate.

15. The method of claim 14, further comprising:
forming a second insulating layer at a side, communicated with a storage layer, of the transistor; wherein the second insulating layer covers the storage layer and is communicated with the first insulating layer.

16. The method of claim 12, further comprising:
forming at least one bit line at a side, away from the surface of the substrate, of the transistor; wherein the bit line is connected to the drain electrode of the transistor.

17. The method of claim 10, wherein the forming the transistor array comprising multiple transistors on the surface of the substrate further comprises:
forming a gate electrode of the transistor at another side opposite to a side, communicated with the storage layer, of the conducting channel; wherein the conducting channel of the transistor is disposed between the gate electrode and the storage layer.

18. The method of claim 17, wherein the forming the gate electrode of the transistor at the another side opposite to the side, communicated with the storage layer, of the conducting channel comprises:
forming a gate electrode oxide layer communicated with the conducting channel at the another side of the conducting channel; and
forming a gate electrode conducting layer communicated with the gate electrode oxide layer at a side of the gate electrode oxide layer; wherein the gate electrode oxide layer is disposed between the gate electrode conducting layer and the conducting channel; or the gate electrode oxide layer wraps the gate electrode conducting layer and is connected to the conducting channel.

19. The method of claim 18, further comprising:
forming a gate electrode protective layer covering the gate at an end, away from the surface of the substrate, of the gate electrode.

20. The method of claim 17, wherein the forming the gate electrode of the transistor at the another side opposite to the side, communicated with the storage layer, of the conducting channel comprises:
forming a penetrated trench at a side of a same row of transistors in the transistor array; and
forming the gate electrodes communicated with the same row of transistors in the trench; wherein the gate electrodes are word lines of the same row of transistors.
